(19) United States
(12) Patent Application Publication
(10) Pub. No.: US 2022/0085197 A1
(43) Pub. Date: Mar. 17, 2022

(54) SEMICONDUCTOR DEVICE, AND METHOD OF MANUFACTURING SEMICONDUCTOR DEVICE

(71) Applicant: Mitsubishi Electric Corporation, Tokyo (JP)

(72) Inventors: Hisashi SAITO, Tokyo (JP); Eiji YAGYU, Tokyo (JP)

(73) Assignee: Mitsubishi Electric Corporation, Tokyo (JP)

(21) Appl. No.: 17/420,393

(22) PCT Filed: Feb. 19, 2019
(86) PCT No.: PCT/JP2019/005955

§ 371 Date: Jul. 2, 2021

(51) Int. Cl. H01L 29/778; H01L 29/20; H01L 29/66

(52) U.S. Cl. CPC H01L 29/7786; H01L 29/66462; H01L 29/2003

(57) ABSTRACT

Provided is a technique capable of suppressing a short channel effect occurring in accordance with miniaturization. A semiconductor device includes: a second nitride semiconductor layer on an upper surface of a first nitride semiconductor layer; a source electrode and a drain electrode on part of an upper surface of the second nitride semiconductor layer; and a gate electrode on a lower surface of the first nitride semiconductor layer between the source electrode and the drain electrode in a plan view, wherein the second nitride semiconductor layer has a larger bandgap than the first nitride semiconductor layer, and the drain electrode is separated from the source electrode.

### TECHNICAL FIELD

A technique disclosed in the specification of the present application relates to a semiconductor device and a method of manufacturing the semiconductor device.

### BACKGROUND ART

A transistor formed on a Ga-plane face where a crystal growth is easily achieved has been used in a conventional high electron mobility transistor (that is to say, HEMT, referred to Patent Document 1).

In a high frequency device field, miniaturization a transistor is required for achieving a high frequency operation and a high output operation of a semiconductor device, however, it is known that a negative effect such as a short channel effect occurs when the transistor is miniaturized too much.

### PRIOR ART DOCUMENTS

### Patent Documents

Patent Document 1: Japanese Patent Application Laid-Open No. 2006-269939

### SUMMARY

### Problem to be Solved by the Invention

As described above, it is important to miniaturize a device to achieve the high frequency operation and the high output operation of a semiconductor device.

In the meanwhile, in the miniaturized transistor, the short channel effect occurs in accordance with the miniaturization in some cases.

The technique disclosed in the specification of the present application therefore has been made to solve problems as described above, and it is an object to provide a technique capable of suppressing a short channel effect occurring in accordance with miniaturization.

### Means to Solve the Problem

A first aspect of a technique disclosed in the specification of the present application includes: a first nitride semiconductor layer; a second nitride semiconductor layer on an upper surface of the first nitride semiconductor layer; a source electrode on part of an upper surface of the second nitride semiconductor layer; a drain electrode on part of an upper surface of the second nitride semiconductor layer; and a gate electrode located on a lower surface of the first nitride semiconductor layer between the source electrode and the drain electrode in a plan view, wherein the second nitride semiconductor layer has a larger bandgap than the first nitride semiconductor layer, and the drain electrode is separated from the source electrode.

A second aspect of a technique disclosed in the specification of the present application includes: forming a second nitride semiconductor layer on a first nitride semiconductor layer; forming a source electrode on part of an upper surface of the second nitride semiconductor layer; forming a drain electrode on part of the upper surface of the second nitride semiconductor layer; and forming a gate electrode on a lower surface of the first nitride semiconductor layer between the source electrode and the drain electrode in a plan view, wherein the second nitride semiconductor layer has a larger bandgap than the first nitride semiconductor layer, and the drain electrode is separated from the source electrode.

### Effects of the Invention

A first aspect of a technique disclosed in the specification of the present application includes: a first nitride semiconductor layer; a second nitride semiconductor layer on an upper surface of the first nitride semiconductor layer; a source electrode on part of an upper surface of the second nitride semiconductor layer; a drain electrode on part of an upper surface of the second nitride semiconductor layer; and a gate electrode located on a lower surface of the first nitride semiconductor layer between the source electrode and the drain electrode in a plan view, wherein the second nitride semiconductor layer has a larger bandgap than the first nitride semiconductor layer, and the drain electrode is separated from the source electrode. According to such a configuration, a short channel effect occurring in accordance with miniaturization of the device can be suppressed.

A second aspect of a technique disclosed in the specification of the present application includes: forming a second nitride semiconductor layer on a first nitride semiconductor layer; forming a source electrode on part of an upper surface of the second nitride semiconductor layer; forming a drain electrode on part of the upper surface of the second nitride semiconductor layer; and forming a gate electrode on a lower surface of the first nitride semiconductor layer between the source electrode and the drain electrode in a plan view, wherein the second nitride semiconductor layer has a larger bandgap than the first nitride semiconductor layer, and the drain electrode is separated from the source electrode. According to such a configuration, a short channel effect occurring in accordance with miniaturization of the device can be suppressed.

These and other objects, features, aspects and advantages relating to the technique disclosed in the specification of the present application will become more apparent from the following detailed description of the present invention when taken in conjunction with the accompanying drawings.

### BRIEF DESCRIPTION OF DRAWINGS

FIG. 1 A cross-sectional view schematically illustrating an example of a configuration of a semiconductor device according to an embodiment.

FIG. 2 A cross-sectional view schematically illustrating an example of a configuration of the semiconductor device according to the embodiment.

FIG. 3 A cross-sectional view schematically illustrating an example of a configuration of the semiconductor device according to the embodiment.

FIG. 4 A cross-sectional view schematically illustrating an example of a configuration of the semiconductor device according to the embodiment.

FIG. 5 A cross-sectional view schematically illustrating an example of a configuration of the semiconductor device according to the embodiment.

FIG. 6 A cross-sectional view schematically illustrating an example of a configuration of the semiconductor device according to the embodiment.

FIG. 7 A cross-sectional view schematically illustrating an example of a configuration of the semiconductor device according to the embodiment.

FIG. 8 A cross-sectional view schematically illustrating an example of a configuration of the semiconductor device according to the embodiment.

### DESCRIPTION OF EMBODIMENT(S)

An embodiment is described hereinafter with reference to the accompanying drawings. Detailed features are also described for explaining a technique in the embodiments hereinafter, however, they are only an exemplification, thus are not always necessary to be able to implement the embodiment. Examples of effects generated by each embodiment are collectively described after the description regarding all the embodiments.

The drawings are schematically illustrated, thus omission or simplification of the configuration is performed on the drawings for explanatory convenience. A mutual relationship of sizes and positions of configurations illustrated in the different drawing is not necessarily accurately illustrated, but can be appropriately changed. A hatching may be drawn in a plan view, for example, as well as a cross-sectional view to easily understand contents of the embodiment.

In the description hereinafter, the same reference numerals are assigned to the similar constituent elements in the illustration, and the same applies to names and functions thereof. Accordingly, the detailed description on them may be omitted to avoid a repetition in some cases.

In the following description, even when terms indicating a specific position and direction such as “upper”, “lower”, “left”, “right”, “side”, “bottom”, “front” or “rear” are stated, the terms are used to facilitate understanding of embodiments for convenience, and therefore, irrelevant to directions in practical implementation.

When “an upper surface of . . . ” or “a lower surface of . . . ” is described in the description hereinafter, it also includes a state where the other constituent element is formed on an upper surface of a target constituent element in addition to the upper surface of the target constituent element. That is to say, when there is a description of “A provided on an upper surface of B”, for example, an intervention of the other constituent element “C” between A and B is not hindered.

Further, in the following description, even when ordinal numbers such as “first” or “second” are stated, the terms are used to facilitate understanding of embodiments, and therefore, the usage of the ordinal numbers does not limit the indication of the ordinal numbers to ordering.

“A nitride semiconductor” in the embodiments hereinafter is a collective term of GaN, AlN, InN and an intermediate composition thereof.

### First Embodiment

A semiconductor device and a method of manufacturing the semiconductor device relating to the present embodiment are described hereinafter.

<Configuration of Semiconductor Device>

FIG. 1 is a cross-sectional view schematically illustrating an example of a configuration of a semiconductor device according to the present embodiment. The semiconductor device relating to the present embodiment is a transistor using a nitride semiconductor, for example.

As exemplified in FIG. 1, a transistor 100 includes a semiconductor substrate 10, a buffer layer 11 formed on an upper surface of the semiconductor substrate 10, a semiconductor layer 12 formed on an upper surface of the buffer layer 11, and a semiconductor layer 13 formed on upper surface of the semiconductor layer 12.

The semiconductor substrate 10 is made of silicon, silicon carbide, or sapphire, for example. The buffer layer 11 has a function of reducing a lattice mismatch between the semiconductor substrate 10 and the semiconductor layer 12. The buffer layer 11 is made of aluminum nitride, for example.

Both the semiconductor layer 12 and the semiconductor layer 13 are made of a nitride semiconductor. The nitride semiconductor constituting the semiconductor layer 12 has a smaller bandgap than the nitride semiconductor constituting the semiconductor layer 13. A magnitude relationship of the bandgap can be determined by analyzing a composition of the nitride semiconductor.

The semiconductor layer 12 is made of undoped GaN, for example. The semiconductor layer 12 may include impurity such as Fe or C for purpose of achieving high resistance. A film thickness of the semiconductor layer 12 is equal to or larger than 0.5 μm and equal to or smaller than 2 μm, for example.

The semiconductor layer 13 is made of undoped AlGaN, for example. A film thickness of the semiconductor layer 13 is equal to or larger than 10 nm and equal to or smaller than 30 nm, for example.

A hetero junction is formed in an interface between the semiconductor layer 13 and the semiconductor layer 12. 2-dimensional electron gas, that is to say, 2DEG is formed in the interface. The 2DEG functions as a carrier of the transistor 100.

A source electrode 14 and a drain electrode 15 are formed separately from each other on an upper surface of the semiconductor layer 13. The source electrode 14 and the drain electrode 15 are metal electrode, for example, and include aluminum, for example.

The source electrode 14 and the drain electrode 15 preferably have ohmic contact with the semiconductor layer 13.

Each of the source electrode 14 and the drain electrode 15 are formed on a Ga plane. The ohmic contact can be achieved by a well-known method, thus the ohmic contact can be formed more easily than a structure described in Non-Patent Document 1, for example.

Ion implantation may be performed on a semiconductor region located below the source electrode 14 (referred to as a source electrode region hereinafter) and a semiconductor region located below the drain electrode 15 (referred to as a drain electrode region hereinafter) so that they have an N-type conductivity. Silicon, for example, may be ion-implanted so that they have the N-type conductivity. Activation processing is performed by thermal treatment after the ion implantation.

<Method of Manufacturing Semiconductor Device>

A trench 16 passing through the semiconductor substrate 10 and the buffer layer 11 and having a bottom part reaching an inner part of the semiconductor layer 12 is formed in the transistor 100.

The trench 16 is formed by reactive ion etching, that is to say, RIE method performed from a side of the semiconductor substrate 10, for example.

Photolithography, for example, is used as a method of forming the trench 16 between the source electrode 14 and the drain electrode 15 in a plan view.

A gate electrode 17 is formed on the bottom part of the trench 16, that is to say, a surface inside the trench 16 having contact with the semiconductor layer 12. Metal such as Ni or Pt, for example, can be applied to the gate electrode 17, however, P-type polysilicon doped with boron or N-type polysilicon doped with phosphorus may also be applied.

A distance from the bottom part of the trench 16 to a lower surface of the semiconductor layer 13 is preferably three times as long as a gate length or less, for example.

A side surface 16a of the trench 16, a side surface 16b of the trench 16 on a side opposite to the side surface 16a, and the bottom part of the trench 16 other than a portion where the gate electrode 17 is formed is preferably covered by a dielectric film, for example. The dielectric film is formed by CVD method, for example. Examples of a material of the dielectric film include SiO₂ or SiN.

As described above, in the transistor 100 relating to the present embodiment, the source electrode 14 and the drain electrode 15 are formed on the Ga plane (the upper surface) of the semiconductor layer 13 made of a nitride semiconductor, and the gate electrode 17 is formed on an N plane (a lower surface) of the semiconductor layer 12 made of a nitride semiconductor.

The gate electrode 17 is located on the lower surface of the semiconductor layer 12 between the source electrode 14 and the drain electrode 15 in a plan view.

Accordingly, when the transistor 100 is viewed from a side of the gate electrode 17, the semiconductor layer 13 made of the nitride semiconductor having the larger bandgap than that constituting the semiconductor layer 12 is located on a lower side of the semiconductor layer 12 having contact with the gate electrode 17 (that is to say, an upper side in FIG. 1), thus the lower side of the gate electrode 17 (that is to say, the upper side in FIG. 1) has high potential controllability. Thus, it is recognized that a device structure for suppressing a short channel effect is achieved.

### Second Embodiment

A semiconductor device and a method of manufacturing the semiconductor device relating to the present embodiment are described. In the description hereinafter, the same reference numerals as those described in the above embodiment will be assigned to the similar constituent elements in the drawings, and detailed description thereof is appropriately omitted.

<Configuration of Semiconductor Device>

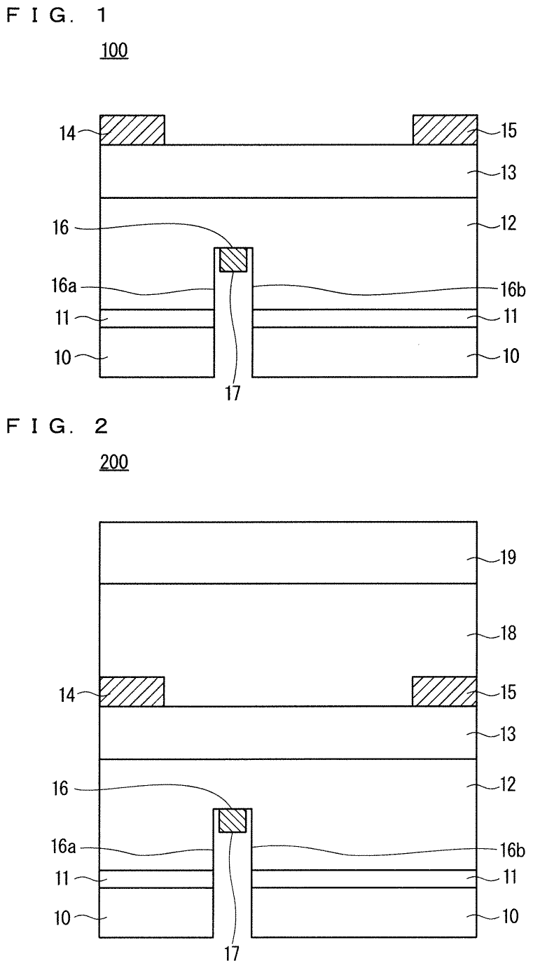

FIG. 2 is a cross-sectional view schematically illustrating an example of a configuration of a semiconductor device according to the present embodiment. The semiconductor device relating to the present embodiment is a transistor using a nitride semiconductor, for example.

As exemplified in FIG. 2, a transistor 200 includes the semiconductor substrate 10, the buffer layer 11, the semiconductor layer 12, the semiconductor layer 13, the source electrode 14, and the drain electrode 15.

A trench 16 passing through the semiconductor substrate 10 and the buffer layer 11 and having a bottom part reaching an inner part of the semiconductor layer 12 is formed in the transistor 200. The gate electrode 17 is formed on the bottom part of the trench 16.

The transistor 200 includes a dielectric layer 18 provided to cover the source electrode 14, the drain electrode 15, and the semiconductor layer 13 and a support substrate 19 provided on an upper surface of the dielectric layer 18.

<Method of Manufacturing Semiconductor Device>

The dielectric layer 18 is formed by chemical vapor deposition, that is to say, CVD method which is one example of vapor growth method. SiO₂ or SiN, for example, is used as a material of the dielectric layer 18. The support substrate 19 may be made up of a semiconductor such as silicon, for example, or may also be made up of glass or diamond.

The support substrate 19 may be formed by being attached to the dielectric layer 18 by an adhesive agent, or may also be formed as a film by CVD method which is one example of vapor growth method, for example.

When the support substrate 19 is formed by a method of attaching the support substrate 19 with an adhesive agent, for example, a process of forming the source electrode 14 and a process of forming the drain electrode 15, each of which is a high-temperature thermal treatment process, are performed before attaching the support substrate 19. Thus, a peeling of the support substrate 19 from an attaching surface due to the high-temperature thermal treatment can be prevented.

When the support substrate 19 is formed by a method of forming a film by CVD method, for example, the gate electrode 17 having low heat resistance is formed after the process of forming the support substrate 19, that is to say, a high-temperature film forming process (of diamond, for example). Thus, a deterioration of the gate electrode 17 due to the thermal treatment can be prevented.

### Third Embodiment

A semiconductor device relating to the present embodiment is described. In the description hereinafter, the same reference numerals as those described in the above embodiment will be assigned to the similar constituent elements in the drawings, and detailed description thereof is appropriately omitted.

<Configuration of Semiconductor Device>

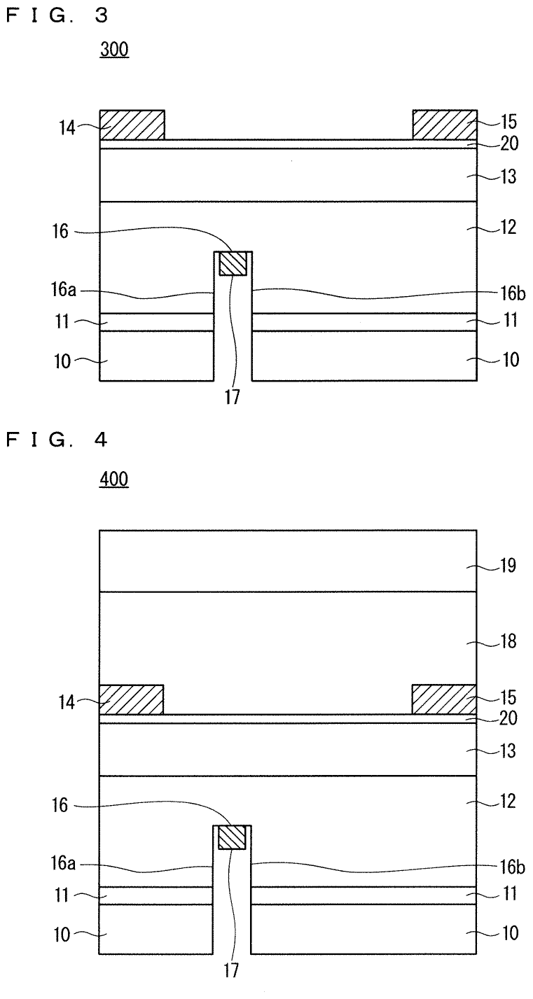

FIG. 3 is a cross-sectional view schematically illustrating an example of a configuration of a semiconductor device according to the present embodiment. The semiconductor device relating to the present embodiment is a transistor using a nitride semiconductor, for example.

As exemplified in FIG. 3, a transistor 300 includes the semiconductor substrate 10, the buffer layer 11, the semiconductor layer 12, the semiconductor layer 13, a semiconductor layer 20 formed on the upper surface of the semiconductor layer 13, the source electrode 14 formed on an upper surface of the semiconductor layer 20, and the drain electrode 15 formed on the upper surface of the semiconductor layer 20 separately from the source electrode 14.

The trench 16 passing through the semiconductor substrate 10 and the buffer layer 11 and having a bottom part reaching the inner part of the semiconductor layer 12 is formed in the transistor 300. The gate electrode 17 is formed on the bottom part of the trench 16.

The semiconductor layer 20 is made of a nitride semiconductor. The nitride semiconductor constituting the semiconductor layer 20 has a smaller bandgap than the nitride semiconductor constituting the semiconductor layer 13.

The semiconductor layer 20 is made of undoped GaN, for example. A film thickness of the semiconductor layer 20 is equal to or larger than 0.5 nm and equal to or smaller than 5 nm, for example.

GaN is excellent in oxidation resistance and chemical resistance compared with AlGaN. Thus, according to the transistor 300 relating to the present embodiment, a damage on a surface of the semiconductor layer at the time of manufacturing process can be reduced.

### Fourth Embodiment

A semiconductor device and a method of manufacturing the semiconductor device relating to the present embodiment are described. In the description hereinafter, the same reference numerals as those described in the above embodiment will be assigned to the similar constituent elements in the drawings, and detailed description thereof is appropriately omitted.

<Configuration of Semiconductor Device>

FIG. 4 is a cross-sectional view schematically illustrating an example of a configuration of a semiconductor device according to the present embodiment. The semiconductor device relating to the present embodiment is a transistor using a nitride semiconductor, for example.

As exemplified in FIG. 4, a transistor 400 includes the semiconductor substrate 10, the buffer layer 11, the semiconductor layer 12, the semiconductor layer 13, the semiconductor layer 20, the source electrode 14, the drain electrode 15, the dielectric layer 18 provided to cover the source electrode 14, the drain electrode 15, and the semiconductor layer 20, and the support substrate 19.

The trench 16 passing through the semiconductor substrate 10 and the buffer layer 11 and having a bottom part reaching the inner part of the semiconductor layer 12 is formed in the transistor 400. The gate electrode 17 is formed on the bottom part of the trench 16.

The semiconductor layer 20 is made of a nitride semiconductor. The semiconductor layer 20 has a bandgap smaller than the semiconductor layer 13.

The semiconductor layer 20 is made of undoped GaN, for example. A film thickness of the semiconductor layer 20 is equal to or larger than 0.5 nm and equal to or smaller than 5 nm, for example.

<Method of Manufacturing Semiconductor Device>

The dielectric layer 18 is formed by CVD method, for example. SiO₂ or SiN, for example, is used as a material of the dielectric layer 18. The support substrate 19 may be made up of a semiconductor such as silicon, for example, or may also be made up of glass or diamond.

The support substrate 19 may be formed by being attached to the dielectric layer 18 by an adhesive agent, or may also be formed as a film by CVD method, for example.

When the support substrate 19 is formed by a method of attaching the support substrate 19 with an adhesive agent, for example, a process of forming the source electrode 14 and a process of forming the drain electrode 15, each of which is a high-temperature thermal treatment process, are performed before attaching the support substrate 19. Thus, the peeling of the support substrate 19 from the attaching surface due to the high-temperature thermal treatment can be prevented.

When the support substrate 19 is formed by a method of forming a film by CVD method, for example, the gate electrode 17 having low heat resistance is formed after a high-temperature film forming process (of diamond, for example). Thus, a deterioration of the gate electrode 17 due to the thermal treatment can be prevented.

GaN is excellent in oxidation resistance and chemical resistance compared with AlGaN. Thus, according to the transistor 400 relating to the present embodiment, a damage on a surface of the semiconductor layer at the time of manufacturing process can be reduced.

### Fifth Embodiment

A semiconductor device and a method of manufacturing the semiconductor device relating to the present embodiment are described. In the description hereinafter, the same reference numerals as those described in the above embodiment will be assigned to the similar constituent elements in the drawings, and detailed description thereof is appropriately omitted.

<Configuration of Semiconductor Device>

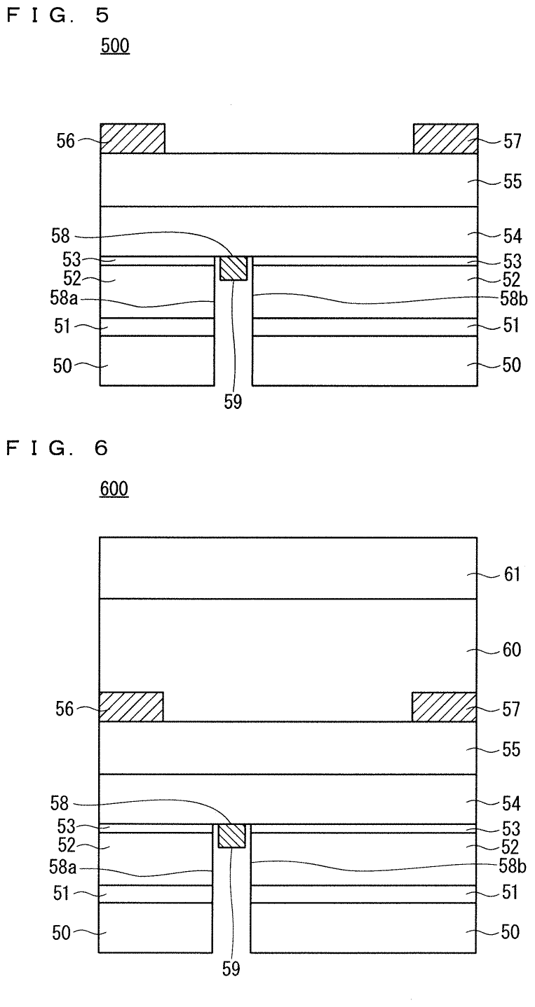

FIG. 5 is a cross-sectional view schematically illustrating an example of a configuration of a semiconductor device according to the present embodiment. The semiconductor device relating to the present embodiment is a transistor using a nitride semiconductor, for example.

As exemplified in FIG. 5, a transistor 500 includes a semiconductor substrate 50, a buffer layer 51 formed on an upper surface of the semiconductor substrate 50, a semiconductor layer 52 formed on an upper surface of the buffer layer 51, a semiconductor layer 53 formed on an upper surface of the semiconductor layer 52, a semiconductor layer 54 formed on an upper surface of the semiconductor layer 53, and a semiconductor layer 55 formed on upper surface of the semiconductor layer 54.

The semiconductor substrate 50 is made of silicon, silicon carbide, or sapphire, for example. The buffer layer 51 has a function of reducing a lattice mismatch between the semiconductor substrate 50 and the semiconductor layer 52. The buffer layer 51 is made of aluminum nitride, for example.

All of the semiconductor layer 52, the semiconductor layer 53, the semiconductor layer 54, and the semiconductor layer 55 are made of a nitride semiconductor. The nitride semiconductor constituting the semiconductor layer 52 has a smaller bandgap than the nitride semiconductor constituting the semiconductor layer 53.

The nitride semiconductor constituting the semiconductor layer 54 has a smaller bandgap than the nitride semiconductor constituting the semiconductor layer 53. The nitride semiconductor constituting the semiconductor layer 55 has a larger bandgap than the nitride semiconductor constituting the semiconductor layer 54.

A magnitude relationship of the bandgap can be determined by analyzing a composition of the nitride semiconductor.

The semiconductor layer 52 is made of undoped GaN, for example. The semiconductor layer 52 may include impurity such as Fe or C for purpose of achieving high resistance. A film thickness of the semiconductor layer 52 is equal to or larger than 0.5 μm and equal to or smaller than 2 μm, for example.

The semiconductor layer 53 is made of undoped AlGaN, for example. A film thickness of the semiconductor layer 53 is equal to or larger than 1 nm and equal to or smaller than 10 nm, for example.

The semiconductor layer 54 is made of undoped GaN, for example. A film thickness of the semiconductor layer 54 is equal to or larger than 0.1 μm and equal to or smaller than 1 μm, for example.

The semiconductor layer 55 is made of undoped AlGaN, for example. A film thickness of the semiconductor layer 55 is equal to or larger than 10 nm and equal to or smaller than 30 nm, for example.

A hetero junction is formed in an interface between the semiconductor layer 55 and the semiconductor layer 54. 2DEG is formed in the interface. The 2DEG functions as a carrier of the transistor 100.

A source electrode 56 and a drain electrode 57 are formed separately from each other on an upper surface of the semiconductor layer 55 by photolithography, for example. The source electrode 56 and the drain electrode 57 are metal electrode, for example, and include aluminum, for example.

The source electrode 56 and the drain electrode 57 preferably have ohmic contact with the semiconductor layer 55.

Each of the source electrode 56 and the drain electrode 57 are formed on a Ga plane. The ohmic contact can be achieved by a well-known method, thus the ohmic contact can be formed more easily than a structure described in Non-Patent Document 1, for example.

Ion implantation may be performed on a semiconductor region located below the source electrode 56 (referred to as a source electrode region hereinafter) and a semiconductor region located below the drain electrode 57 (referred to as a drain electrode region hereinafter) so that they have an N-type conductivity. Silicon, for example, may be ion-implanted so that they have the N-type conductivity. Activation processing is performed by thermal treatment after the ion implantation.

<Method of Manufacturing Semiconductor Device>

A trench 58 passing through the semiconductor substrate 50, the buffer layer 51, the semiconductor layer 52, and the semiconductor layer 53 and having a bottom part reaching a lower surface of the semiconductor layer 54 is formed in the transistor 500.

The trench 58 is formed by RIE method from a side of the semiconductor substrate 50, for example.

Photolithography, for example, is used as a method of forming the trench 58 between the source electrode 56 and the drain electrode 57 in a plan view.

A gate electrode 59 is formed on the bottom part of the trench 58, that is to say, a surface inside the trench 58 having contact with the lower surface of the semiconductor layer 54. In other words, the gate electrode 59 is provided on the lower surface of the semiconductor layer 54 not covered by the semiconductor layer 53 and the semiconductor layer 52 but exposed outside. Metal such as Ni or Pt, for example, can be applied to the gate electrode 59, however, P-type polysilicon doped with boron or N-type polysilicon doped with phosphorus may also be applied.

A side surface 58a of the trench 58, a side surface 58b of the trench 58 on a side opposite to the side surface 58a, and the bottom part of the trench 58 other than a portion where the gate electrode 59 is formed is preferably covered by a dielectric film, for example. The dielectric film is formed by CVD method, for example. Examples of a material of the dielectric film include SiO₂ or SiN.

As described above, in the transistor 500 relating to the present embodiment, the source electrode 56 and the drain electrode 57 are formed on the Ga plane of the semiconductor layer 55 made of a nitride semiconductor, and the gate electrode 59 is formed on an N plane of the semiconductor layer 54 made of a nitride semiconductor.

The gate electrode 59 is located on the lower surface of the semiconductor layer 54 between the source electrode 56 and the drain electrode 57 in a plan view.

Accordingly, when the transistor 500 is viewed from a side of the gate electrode 59, the semiconductor layer 55 made of the nitride semiconductor having the larger bandgap than that constituting the semiconductor layer 54 is located on a lower side of the semiconductor layer 54 having contact with the gate electrode 59 (that is to say, an upper side in FIG. 1), thus the lower side of the gate electrode 59 (that is to say, the upper side in FIG. 1) has high potential controllability. Thus, it is recognized that a device structure for suppressing a short channel effect is achieved.

The semiconductor layer 53 is made of AlN, an etching rate can be slowed compared with a case where the semiconductor layer 53 is made of GaN. For example, when etching gas including fluorine is used for etching, an etching speed of AlN rapidly decreases.

Thus, when the semiconductor layer 53 is formed between the semiconductor layer 52 and the semiconductor layer 54, high etching selectivity can be obtained in performing the etching from a side of the semiconductor layer 52. Thus, a processing accuracy of the trench 58 can be improved.

### Sixth Embodiment

A semiconductor device and a method of manufacturing the semiconductor device relating to the present embodiment are described. In the description hereinafter, the same reference numerals as those described in the above embodiment will be assigned to the similar constituent elements in the drawings, and detailed description thereof is appropriately omitted.

<Configuration of Semiconductor Device>

FIG. 6 is a cross-sectional view schematically illustrating an example of a configuration of a semiconductor device according to the present embodiment. The semiconductor device relating to the present embodiment is a transistor using a nitride semiconductor, for example.

As exemplified in FIG. 6, a transistor 600 includes the semiconductor substrate 50, the buffer layer 51, the semiconductor layer 52, the semiconductor layer 53, the semiconductor layer 54, the semiconductor layer 55, the source electrode 56, and the drain electrode 57.

<Method of Manufacturing Semiconductor Device>

A trench 58 passing through the semiconductor substrate 50, the buffer layer 51, the semiconductor layer 52, and the semiconductor layer 53 and having a bottom part reaching a lower surface of the semiconductor layer 54 is formed in the transistor 600. The gate electrode 59 is formed on the bottom part of the trench 58.

The transistor 600 includes a dielectric layer 60 provided to cover the source electrode 56, the drain electrode 57, and the semiconductor layer 55 and a support substrate 61 provided on an upper surface of the dielectric layer 60.

The dielectric layer 60 is formed by CVD method, for example. SiO₂ or SiN, for example, is used as a material of the dielectric layer 60. The support substrate 61 may be made up of a semiconductor such as silicon, for example, or may also be made up of glass or diamond.

The support substrate 61 may be formed by being attached to the dielectric layer 60 by an adhesive agent, or may also be formed as a film by CVD method, for example.

When the support substrate 61 is formed by a method of attaching the support substrate 61 with an adhesive agent, for example, a process of forming the source electrode 56 and a process of forming the drain electrode 57, each of which is a high-temperature thermal treatment process, are performed before attaching the support substrate 61. Thus, the peeling of the support substrate 61 from the attaching surface due to the high-temperature thermal treatment can be prevented.

When the support substrate 61 is formed by a method of forming a film by CVD method, for example, the gate electrode 59 having low heat resistance is formed after a high-temperature film forming process (of diamond, for example). Thus, a deterioration of the gate electrode 59 due to the thermal treatment can be prevented.

### Seventh Embodiment

A semiconductor device relating to the present embodiment is described. In the description hereinafter, the same reference numerals as those described in the above embodiment will be assigned to the similar constituent elements in the drawings, and detailed description thereof is appropriately omitted.

<Configuration of Semiconductor Device>

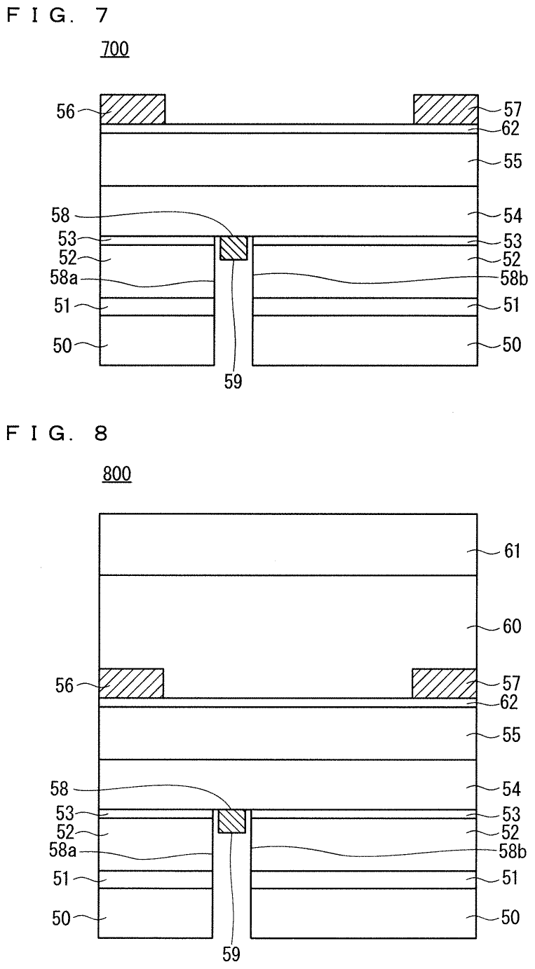

FIG. 7 is a cross-sectional view schematically illustrating an example of a configuration of a semiconductor device according to the present embodiment. The semiconductor device relating to the present embodiment is a transistor using a nitride semiconductor, for example.

As exemplified in FIG. 7, a transistor 700 includes the semiconductor substrate 50, the buffer layer 51, the semiconductor layer 52, the semiconductor layer 53, the semiconductor layer 54, the semiconductor layer 55, a semiconductor layer 62 formed on the upper surface of the semiconductor layer 55, the source electrode 56 formed on an upper surface of the semiconductor layer 62, and the drain electrode 57 formed on the upper surface of the semiconductor layer 62 separately from the source electrode 56.

The semiconductor layer 62 is made of a nitride semiconductor. The nitride semiconductor constituting the semiconductor layer 62 has a smaller bandgap than the nitride semiconductor constituting the semiconductor layer 55.

The semiconductor layer 62 is made of undoped GaN, for example. A film thickness of the semiconductor layer 62 is equal to or larger than 0.5 nm and equal to or smaller than 5 nm, for example.

GaN is excellent in oxidation resistance and chemical resistance compared with AlGaN. Thus, according to the transistor 700 relating to the present embodiment, a damage on a surface of the semiconductor layer at the time of manufacturing process can be reduced.

### Eighth Embodiment

A semiconductor device and a method of manufacturing the semiconductor device relating to the present embodiment are described. In the description hereinafter, the same reference numerals as those described in the above embodiment will be assigned to the similar constituent elements in the drawings, and detailed description thereof is appropriately omitted.

<Configuration of Semiconductor Device>

FIG. 8 is a cross-sectional view schematically illustrating an example of a configuration of a semiconductor device according to the present embodiment. The semiconductor device relating to the present embodiment is a transistor using a nitride semiconductor, for example.

As exemplified in FIG. 8, a transistor 800 includes the semiconductor substrate 50, the buffer layer 51, the semiconductor layer 52, the semiconductor layer 53, the semiconductor layer 54, the semiconductor layer 55, the source electrode 56, the drain electrode 57, the dielectric layer 60 provided to cover the source electrode 56, the drain electrode 57, and the semiconductor layer 62, and the support substrate 61.

<Method of Manufacturing Semiconductor Device>

The dielectric layer 60 is formed by CVD method, for example. SiO₂ or SiN, for example, is used as a material of the dielectric layer 60. The support substrate 61 may be made up of a semiconductor such as silicon, for example, or may also be made up of glass or diamond.

The support substrate 61 may be formed by being attached to the dielectric layer 60 by an adhesive agent, or may also be formed as a film by CVD method, for example.

When the support substrate 61 is formed by a method of attaching the support substrate 61 with an adhesive agent, for example, a process of forming the source electrode 56 and a process of forming the drain electrode 57, each of which is a high-temperature thermal treatment process, are performed before attaching the support substrate 61. Thus, the peeling of the support substrate 61 from the attaching surface due to the high-temperature thermal treatment can be prevented.

When the support substrate 61 is formed by a method of forming a film by CVD method, for example, the gate electrode 59 having low heat resistance is formed after a high-temperature film forming process (of diamond, for example). Thus, a deterioration of the gate electrode 59 due to the thermal treatment can be prevented.

### Effects Generated by Embodiments Described Above

Examples of effects generated by the above embodiments are described hereinafter. It should be noted that, in the following description, the effects are described based on the specific configurations illustrated in the above described embodiments, however, other specific configurations may be applied in place of the configurations illustrated in the specification, within the scope of producing the similar effects.

Also, the replacement may be implemented with a plurality of embodiments. That is to say, each of the configurations illustrated in the corresponding embodiments may be combined with one another to produce the similar effects.

According to the embodiments described above, the semiconductor device includes a first nitride semiconductor layer, a second nitride semiconductor layer, the source electrode 14 (or the source electrode 56), the drain electrode 15 (or the drain electrode 57), and the gate electrode 17 (or the gate electrode 59). Herein, the first nitride semiconductor layer corresponds to one of the semiconductor layer 12 and the semiconductor layer 54, for example. The second nitride semiconductor layer corresponds to one of the semiconductor layer 13 and the semiconductor layer 55, for example. The semiconductor layer 13 is provided on the upper surface of the semiconductor layer 12. The source electrode 14 is partially provided on the upper surface of the semiconductor layer 13. The drain electrode 15 is partially provided on the upper surface of the semiconductor layer 13. The gate electrode 17 is located on the lower surface of the semiconductor layer 12 between the source electrode 14 and the drain electrode 15 in a plan view. Herein, the semiconductor layer 13 has a bandgap larger than the semiconductor layer 12. The drain electrode 15 is separated from the source electrode 14.

According to such a configuration, a short channel effect occurring in accordance with miniaturization of the device can be suppressed. Specifically, the transistor can be formed using the lower surface (the N plane), thus a short channel effect in accordance with miniaturization of the gate length can be suppressed. The transistor using the N plane can be formed even in a case where the semiconductor substrate 10 in which epitaxial growth is performed in a Ga plane direction, on which crystal growth is generally performed easily, is used.

Even in the case where at least one of the other configurations other than the configurations illustrated in the specification of the present application is appropriately added to the configuration described above, that is to say, other configurations other than the configurations illustrated in the specification of the present application, which are not referred to as configurations described above are appropriately added, the similar effects can be produced.

According to the embodiments described above, the lower surface of the semiconductor layer 12 is the N plane. According to such a configuration, the transistor using the N plane can be formed.

According to the embodiments described above, the semiconductor layer 12 is made of GaN. According to such a configuration, the transistor using the N plane can be formed even in the case where the semiconductor substrate 10 in which epitaxial growth is performed in the Ga plane direction is used.

According to the embodiments described above, the upper surface of the semiconductor layer 13 is the Ga plane. According to such a configuration, the transistor can be formed using the semiconductor substrate 10 in which epitaxial growth is performed in the Ga plane direction.

According to the embodiments described above, the trench 16 is formed on the lower surface of the semiconductor layer 12. The gate electrode 17 is provided on the bottom part of the trench 16 in the lower surface of the semiconductor layer 12. According to such a configuration, the transistor using the N plane can be formed even in the case where the semiconductor substrate 10 in which epitaxial growth is performed in the Ga plane direction is used.

According to the embodiments described above, the semiconductor device includes the dielectric layer 18 on the upper surface of the semiconductor layer 13 and the support substrate 19 on the upper surface of the dielectric layer 18. According to such a configuration, the semiconductor substrate 10 can be made to have a thin plate-like shape from a side of the lower surface while being supported by the support substrate 19. Accordingly, a processing accuracy (a positioning accuracy) of the semiconductor substrate 10 can be improved.

According to the embodiments described above, the support substrate 19 is made of diamond. According to such a configuration, sufficient heat radiation property for a heat generation at a time device operation can be achieved.

According to the embodiments described above, the semiconductor device includes a third nitride semiconductor layer on the upper surface of the semiconductor layer 13. Herein, the third nitride semiconductor layer corresponds to one of the semiconductor layer 20 and the semiconductor layer 62, for example. The source electrode 14 is provided on part of the upper surface of the semiconductor layer 20. The drain electrode 15 is provided on part of the upper surface of the semiconductor layer 20. According to such a configuration, the semiconductor layer 20 (the cap layer) which is made of GaN is formed on the upper surface of the semiconductor layer 13 which is made of AlGaN, thus medical solution resistance, for example, is improved.

According to the embodiments described above, the semiconductor device includes a fourth nitride semiconductor layer and a fifth nitride semiconductor layer. Herein, the fourth nitride semiconductor layer corresponds to the semiconductor layer 53, for example. Herein, the fifth nitride semiconductor layer corresponds to the semiconductor layer 52, for example. The semiconductor layer 53 is provided on the lower surface of the semiconductor layer 54. The semiconductor layer 52 is provided on the lower surface of the semiconductor layer 53. The semiconductor layer 53 has a bandgap larger than the semiconductor layer 54 and the semiconductor layer 52. The gate electrode 59 is provided on the lower surface of the semiconductor layer 54 not covered by the semiconductor layer 53 and the semiconductor layer 52 but exposed outside. According to such a configuration, the semiconductor layer 53 can be used as an etching stop layer at a time of performing etching processing on the semiconductor substrate 50 from the side of the lower surface to expose the lower surface of the semiconductor layer 54. Thus, a processing accuracy can be improved.

According to the embodiments described above, the semiconductor layer 13 is formed on the upper surface of the semiconductor layer 12 in the method of manufacturing the semiconductor device. Then, the source electrode 14 is provided on part of the upper surface of the semiconductor layer 13. Then, the drain electrode 15 is formed on part of the upper surface of the semiconductor layer 13. Then, the gate electrode 17 is formed on the lower surface of the semiconductor layer 12 between the source electrode 14 and the drain electrode 15 in a plan view. Herein, the semiconductor layer 13 has a bandgap larger than the semiconductor layer 12. The drain electrode 15 is separated from the source electrode 14.

According to such a configuration, a short channel effect occurring in accordance with miniaturization of the device can be suppressed. Specifically, the transistor can be formed using the lower surface (the N plane), thus a short channel effect in accordance with miniaturization of the gate length can be suppressed.

Even in the case where at least one of the other configurations other than the configurations illustrated in the specification of the present application is appropriately added to the configuration described above, that is to say, other configurations other than the configurations illustrated in the specification of the present application, which are not referred to as configurations described above are appropriately added, the similar effects can be produced.

The order of performing each processing can be changed unless there is a specific limitation.

According to the embodiments described above, the dielectric layer 18 is formed on the upper surface of the semiconductor layer 13. Then, the support substrate 19 is formed on the upper surface of the dielectric layer 18. According to such a configuration, the semiconductor substrate 10 can be made to have a thin plate-like shape from the side of the lower surface while being supported by the support substrate 19. Accordingly, the processing accuracy (the positioning accuracy) of the semiconductor substrate 10 can be improved.

According to the embodiments described above, the support substrate 19 is made of diamond. According to such a configuration, sufficient heat radiation property to endure a high-temperature treatment process can be achieved at a time of processing the semiconductor substrate 10 from the side of the lower surface.

According to the embodiments described above, the support substrate 19 is formed by vapor growth method. According to such a configuration, sufficient heat radiation property to endure a high-temperature treatment process can be achieved at a time of processing the semiconductor substrate 10 from the side of the lower surface.

According to the embodiments described above, the support substrate 19 is attached to and formed on the upper surface of the dielectric layer 18. According to such a configuration, a process of forming the source electrode 14 and a process of forming the drain electrode 15, each of which is a high-temperature thermal treatment process, are performed before attaching the support substrate 19. Thus, the peeling of the support substrate 19 from the attaching surface due to the high-temperature thermal treatment can be prevented.

According to the embodiments described above, the gate electrode 17 is formed on the lower surface of the semiconductor layer 12 after the support substrate 19 is formed. According to such a configuration, the semiconductor substrate 10 can be made to have a thin plate-like shape from the side of the lower surface while being supported by the support substrate 19. Accordingly, the processing accuracy (the positioning accuracy) of the semiconductor substrate 10 can be improved. The gate electrode 17 is formed after the process of forming the support substrate 19, thus a deterioration of the gate electrode 17 due to the thermal treatment can be prevented.

### Modification Example in Embodiments Described Above

In the embodiments described above, material properties, materials, dimensions, shapes, relative arrangement relations, conditions for implementation, and so forth for the respective constituent elements may be described, however, these represent one example in all aspects, and are not limited to the description in the specification of the present application.

Accordingly, it is understood that numerous other modifications variations, and equivalents can be devised without departing from the scope of the technique disclosed in the specification of the present application. For example, the following cases where at least one of the constituent elements is to be modified, added, or omitted, further, at least one of the constituent elements of at least one of the embodiments is extracted and then combined with constituent elements of the other embodiment, are involved.

The “one” constituent element described in the above embodiments may be “one or more” constituent elements so far as consistent with the embodiments.

Further, individual constituent elements are conceptual units. Thus, within the range of the technique disclosed in the specification of the present application, one constituent element may include multiple structures, one constituent element may correspond to part of some structure, and multiple constituent elements may be included in one structure.

Each constituent element includes a structure having a different configuration or a different shape as long as the structure of the different configuration or the different shape achieves the same function in each constituent element in the embodiments described above.

What has been described in the specification of the present application is referred for all purposes regarding the present technique. It is thus not an admission that any of the descriptions provided herein are conventional techniques.

Further, in the embodiments described above, when names of materials are stated unless otherwise specified, an alloy of the material and other additives, and so forth are included, so far as consistent with the embodiments.

### EXPLANATION OF REFERENCE SIGNS

10, 50 semiconductor substrate, 11, 51 buffer layer, 12, 13, 20, 52, 53, 54, 55, 62 semiconductor layer, 14, 56 source electrode, 15, 57 drain electrode, 16, 58 trench, 16a, 16b, 58a, 58b side surface, 17, 59 gate electrode, 18, 60 dielectric layer, 19, 61 support substrate, 100, 200, 300, 400, 500, 600, 700, 800 transistor.

1. A semiconductor device, comprising:
a first nitride semiconductor layer;
a second nitride semiconductor layer on an upper surface of the first nitride semiconductor layer;
a source electrode on part of an upper surface of the second nitride semiconductor layer;
a drain electrode on part of an upper surface of the second nitride semiconductor layer; and
a gate electrode located on a lower surface of the first nitride semiconductor layer between the source electrode and the drain electrode in a plan view, wherein
the second nitride semiconductor layer has a larger bandgap than the first nitride semiconductor layer,
the drain electrode is separated from the source electrode,
a trench is formed on the lower surface of the first nitride semiconductor layer,
the gate electrode is provided on a bottom part of the trench in the lower surface of the first nitride semiconductor layer, and
the gate electrode is not provided in a side part of the trench.

2. The semiconductor device according to claim 1, wherein
the lower surface of the first nitride semiconductor layer is an N plane.

3. The semiconductor device according to claim 1, wherein
the first nitride semiconductor layer is made of GaN.

4. The semiconductor device according to claim 1,
wherein the upper surface of the second nitride semiconductor layer is a Ga plane.

5.-6. (canceled)

7. A semiconductor device, comprising:
a first nitride semiconductor layer;
a second nitride semiconductor layer on an upper surface of the first nitride semiconductor layer;
a source electrode on part of an upper surface of the second nitride semiconductor layer;
a drain electrode on part of an upper surface of the second nitride semiconductor layer; and
a gate electrode located on a lower surface of the first nitride semiconductor layer between the source electrode and the drain electrode in a plan view, wherein
the second nitride semiconductor layer has a larger bandgap than the first nitride semiconductor layer,
the drain electrode is separated from the source electrode,
a trench is formed on the lower surface of the first nitride semiconductor layer,
the gate electrode is provided on a bottom part of the trench in the lower surface of the first nitride semiconductor layer, and
the gate electrode is not provided in a side part of the trench, the semiconductor device further comprising:
a dielectric layer covering the source electrode and the drain electrode on the upper surface of the second nitride semiconductor layer; and
a support substrate on an upper surface of the dielectric layer, wherein
the support substrate is made of diamond.

8. The semiconductor device according to claim 1, further comprising
a third nitride semiconductor layer on the upper surface of the second nitride semiconductor layer, wherein
the source electrode is provided on part of an upper surface of the third nitride semiconductor layer, and
the drain electrode is provided on part of the upper surface of the third nitride semiconductor layer.

9. The semiconductor device according to claim 1, further comprising:
a fourth nitride semiconductor layer on the lower surface of the first nitride semiconductor layer; and
a fifth nitride semiconductor layer on a lower surface of the fourth nitride semiconductor layer; wherein
the fourth nitride semiconductor layer has a larger bandgap than the first nitride semiconductor layer and the fifth nitride semiconductor layer, and
the gate electrode is provided on the lower surface of the first nitride semiconductor layer not covered by the fourth semiconductor layer and the fifth semiconductor layer but exposed outside.

10.-14. (canceled)

15. A method of manufacturing the semiconductor device, comprising:
forming a second nitride semiconductor layer on an upper surface of a first nitride semiconductor layer;
forming a source electrode on part of an upper surface of the second nitride semiconductor layer;
forming a drain electrode on part of the upper surface of the second nitride semiconductor layer; and
forming a gate electrode on a lower surface of the first nitride semiconductor layer between the source electrode and the drain electrode in a plan view, wherein
the second nitride semiconductor layer has a larger bandgap than the first nitride semiconductor layer, and
the drain electrode is separated from the source electrode, the method further comprising:
forming a dielectric layer covering the source electrode and the drain electrode on the upper surface of the second nitride semiconductor layer; and
forming a support substrate on an upper surface of the dielectric layer, wherein the support substrate is made of diamond,
the support substrate is attached to and formed on the upper surface of the dielectric layer, and
the gate electrode is formed on the lower surface of the first nitride semiconductor layer after the support substrate is formed.

16. The semiconductor device according to claim 1, wherein
a lower surface of the gate electrode is located closer to a lower surface of the second nitride semiconductor layer in relation to the lower surface of the first nitride semiconductor layer.

17. The semiconductor device according to claim 7, wherein
a lower surface of the gate electrode is located closer to a lower surface of the second nitride semiconductor layer in relation to the lower surface of the first nitride semiconductor layer.

18. The semiconductor device according to claim 7, wherein
the lower surface of the first nitride semiconductor layer is an N plane.

19. The semiconductor device according to claim 7, wherein
the first nitride semiconductor layer is made of GaN.

20. The semiconductor device according to claim 7, wherein
the upper surface of the second nitride semiconductor layer is a Ga plane.

21. The semiconductor device according to claim 7, further comprising
a third nitride semiconductor layer on the upper surface of the second nitride semiconductor layer, wherein
the source electrode is provided on part of an upper surface of the third nitride semiconductor layer, and
the drain electrode is provided on part of the upper surface of the third nitride semiconductor layer.

22. The semiconductor device according to claim 7, further comprising:
a fourth nitride semiconductor layer on the lower surface of the first nitride semiconductor layer; and
a fifth nitride semiconductor layer on a lower surface of the fourth nitride semiconductor layer; wherein
the fourth nitride semiconductor layer has a larger bandgap than the first nitride semiconductor layer and the fifth nitride semiconductor layer, and
the gate electrode is provided on the lower surface of the first nitride semiconductor layer not covered by the fourth semiconductor layer and the fifth semiconductor layer but exposed outside.
